(19) United States
(12) Patent Application Publication
(10) Pub. No.: US 2024/0250012 A1
(43) Pub. Date: Jul. 25, 2024

(54) PACKAGE CARRIER AND MANUFACTURING METHOD THEREOF AND CHIP PACKAGE STRUCTURE

(71) Applicant: Chung W. Ho, Taipei City (TW)

(72) Inventor: Chung W. Ho, Taipei City (TW)

(21) Appl. No.: 18/402,698

(22) Filed: Jan. 2, 2024

(30) Foreign Application Priority Data
Jan. 4, 2023 (TW) 112100272

(51) Int. Cl. H01L 23/498; H01L 23/00; H01L 23/14; H01L 23/31; H01L 25/00; H01L 25/18

(52) U.S. Cl. CPC H01L 23/49838; H01L 23/14; H01L 23/3128; H01L 24/16; H01L 24/32; H01L 24/73; H01L 25/18; H01L 25/50; H01L 2224/16225; H01L 2224/32225; H01L 2224/73204; H01L 2924/1815

(57) ABSTRACT

A package carrier includes a redistribution circuit layer, a plurality of first conductive pillars, and a package mold plate. The redistribution circuit layer has a first surface and a second surface opposite to each other, and includes a plurality of redistribution circuits, a plurality of conductive vias, a plurality of dielectric layers, and a plurality of output pads. The conductive vias are flush with the first surface, and the output pads protrude from the second surface. The first conductive pillars are disposed within the package mold plate, and are adjacent to the first surface of the redistribution circuit layer and also electrically connected to part of the conductive vias. The package mold plate is adjacent to the first surface of the redistribution circuit layer and has a recess in a middle region of the package mold plate. The recess exposes the first conductive pillars. A thickness of an edge region of the package mold plate provides mechanical stability, so that the redistribution circuit layer attached to it on all four sides will not be deformed.

### CROSS-REFERENCE TO RELATED APPLICATION

This application claims the priority benefit of Taiwan application serial no. 112100272, filed on Jan. 4, 2023. The entirety of the above-mentioned patent application is hereby incorporated by reference herein and made a part of specification.

### BACKGROUND

### Technical Field

The disclosure relates to a carrier structure, a manufacturing method thereof, and a package structure, and in particular, to a package carrier, a manufacturing method thereof, and a chip package structure.

### Description of Related Art

In the prior art, when producing a chip-last (or referred to as an RDL first), a circuit layer of a redistribution circuit layer is first produced on a temporary substrate. Next, the redistribution circuit layer needs to be transferred from the original temporary substrate and electrically connected to a second substrate, and debonded with the original temporary substrate. After the board transfer and board removal operations, a composite substrate composed of the redistribution circuit layer and the second substrate can become a product and commodity and undergo electrical testing. The yield loss of one of the two will cause unnecessary loss of the other part, and the redistribution circuit layer itself cannot become a product, which will affect its degree of freedom in design and application.

### SUMMARY

The disclosure provides a package carrier with a smaller yield loss and a better degree of freedom in design and application.

The disclosure also provides a manufacturing method of a package carrier, which is configured to manufacture the above-mentioned redistribution circuit carrier to become an independent product and commodity, thus effectively reducing the production cost.

The disclosure also provides a chip package structure. A package mold plate produced before a chip is mounted eliminates the need to form an encapsulation layer after the chip is mounted, thereby achieving a better package yield.

A package carrier of the disclosure includes a redistribution circuit layer, a plurality of first conductive pillars, and a package mold plate. The redistribution circuit layer has a first surface and a second surface opposite to each other, and includes a plurality of redistribution circuits, a plurality of conductive vias, a plurality of dielectric layers, and a plurality of output pads. The redistribution circuits and the dielectric layers are alternately stacked, and the conductive vias are electrically connected to two adjacent redistribution circuits. The conductive vias are flush with the first surface, and the output pads protrude from the second surface. The first conductive pillars are disposed on the first surface of the redistribution circuit layer and electrically connected to part of the conductive vias. The package mold plate is disposed on the first surface of the redistribution circuit layer and has a recess in a middle region of the package mold plate. The recess exposes the first conductive pillars. The first conductive pillars pass through part of the package mold plate located in the middle region, and a thickness of an edge region of the package mold plate provides mechanical stability.

In an embodiment of the disclosure, a thickness of the package mold plate is greater than or equal to 100 microns and less than or equal to 600 microns.

In an embodiment of the disclosure, a line width of each of the redistribution circuits is greater than or equal to 0.5 microns and less than or equal to 30 microns.

In an embodiment of the disclosure, the package carrier further includes a solder mask, which is disposed on the second surface of the redistribution circuit layer and exposes part of the output pads.

In an embodiment of the disclosure, the package carrier further includes a plurality of second conductive pillars, which penetrate the package mold plate and are electrically connected to the conductive vias of the redistribution circuit layer.

A manufacturing method of a package carrier of the disclosure includes the following steps. A substrate is provided. The substrate includes a base material, a stainless steel layer, and a metal layer. The base material includes a first part and a second part disposed on the first part and exposing part of the first part. The stainless steel layer is located on the base material and conformally covers the base material. The metal layer is formed on the stainless steel layer and conformally covers the stainless steel layer. A plurality of first conductive pillars are formed on the substrate, and the first conductive pillars correspond to the second part of the base material. A package mold plate is formed on the substrate, and the package mold plate covers the metal layer and exposes each of the first conductive pillars. A redistribution circuit layer is provided on the substrate. The redistribution circuit layer has a first surface and a second surface opposite to each other, and includes a plurality of redistribution circuits, a plurality of conductive vias, a plurality of dielectric layers, and a plurality of output pads. The redistribution circuits and the dielectric layers are alternately stacked, and the conductive vias are electrically connected to two adjacent redistribution circuits. The conductive vias are flush with the first surface, and part of the conductive vias are electrically connected to each of the first conductive pillars respectively. The output pads protrude from the second surface. The substrate is removed so that there is a recess in a middle region of the package mold plate. The recess exposes the first conductive pillars. The first conductive pillars pass through part of the package mold plate located in the middle region, and a thickness of an edge region of the package mold plate provides mechanical stability.

In an embodiment of the disclosure, a material of the substrate includes glass.

In an embodiment of the disclosure, the material of the substrate includes fiberglass resin.

In an embodiment of the disclosure, the first part and the second part of the base material are fixed together through an adhesive.

In an embodiment of the disclosure, the manufacturing method of the package carrier further includes forming a plurality of second conductive pillars on the substrate before forming the package mold plate on the substrate, and the second conductive pillars correspond to the first part exposed by the second part of the base material.

In an embodiment of the disclosure, the manufacturing method of the package carrier further includes forming a solder mask on the second surface of the redistribution circuit layer and exposing part of the output pads before removing the substrate.

In an embodiment of the disclosure, the thickness of the package mold plate is greater than or equal to 100 microns and less than or equal to 600 microns.

In an embodiment of the disclosure, a line width of each of the redistribution circuits is greater than or equal to 0.5 microns and less than or equal to 30 microns.

A chip package structure of the disclosure includes a circuit board, a package carrier, and a chip. The package carrier is disposed on the circuit board and electrically connected to the circuit board. The package carrier includes a redistribution circuit layer, a plurality of first conductive pillars, and a package mold plate. The redistribution circuit layer has a first surface and a second surface opposite to each other, and includes a plurality of redistribution circuits, a plurality of conductive vias, a plurality of dielectric layers, and a plurality of output pads. The redistribution circuits and the dielectric layers are alternately stacked, and the conductive vias are electrically connected to two adjacent redistribution circuits. The conductive vias are flush with the first surface, and the output pads protrude from the second surface and are electrically connected to the circuit board. The first conductive pillars are disposed on the first surface of the redistribution circuit layer and electrically connected to part of the conductive vias. The package mold plate is disposed on the first surface of the redistribution circuit layer and has a recess in a middle region of the package mold plate. The recess exposes the first conductive pillars. The first conductive pillars pass through part of the package mold plate located in the middle region, and a thickness of an edge region of the package mold plate provides mechanical stability. The chip is disposed in the recess of the package mold plate and electrically connected to the first conductive pillars.

In an embodiment of the disclosure, the chip package structure further includes a plurality of solder balls and an underfill. The solder balls are disposed between the circuit board and the package carrier. The output pads of the redistribution circuit layer are electrically connected to the circuit board through the solder balls. The underfill is filled between the circuit board and the package carrier and covers the solder balls.

In an embodiment of the disclosure, the chip package structure further includes the underfill, which is filled between the recess of the package mold plate and the chip, and covers the first conductive pillars.

In an embodiment of the disclosure, the chip package structure further includes the plurality of solder balls disposed on a side of the circuit board relatively away from the package carrier.

In an embodiment of the disclosure, a thickness of the package mold plate is greater than or equal to 100 microns and less than or equal to 600 microns.

In an embodiment of the disclosure, a line width of each of the redistribution circuits is greater than or equal to 0.5 microns and less than or equal to 30 microns.

In an embodiment of the disclosure, the package carrier further includes the solder mask, which is disposed on the second surface of the redistribution circuit layer and exposes part of the output pads.

In an embodiment of the disclosure, the package carrier further includes a plurality of second conductive pillars that penetrate the package mold plate and are electrically connected to the conductive vias of the redistribution circuit layer.

In an embodiment of the disclosure, the chip package structure further includes a package on package (POP) component, the plurality of solder balls, and the underfill. The POP component is disposed on the package carrier and electrically connected to the second conductive pillars. The chip is located between the POP component and the circuit board. The solder balls are disposed between the POP component and the second conductive pillars, and the POP component is electrically connected to the second conductive pillars through the solder balls. The underfill is filled between the POP component and the package carrier, between the POP component and the chip, and between the recess of the package mold plate and the chip, and covers the first conductive pillars and the solder balls.

Based on the above, in the design of the package carrier of the disclosure, the thickness of the edge region of the package mold plate can provide mechanical stability, so that the redistribution circuit layer attached to it on all four sides will not be deformed, and the recess in the middle region of the package mold plate can expose the first conductive pillars electrically connected to the conductive vias of the redistribution circuit layer. In this way, by disposing the package mold plate, not only the structural strength of the overall package carrier can be increased, but also the first conductive pillars exposed by the recess and the output pads can be electrically tested at the same time, thus improving the electrical reliability of the package carrier. Furthermore, when the chip is subsequently assembled on the package carrier, since the chip is located in the recess and electrically connected to the first conductive pillars, a better package yield can be achieved to achieve the structure required for the chip last without the need to manufacture an encapsulant. In addition, in the manufacturing method of the package carrier of the embodiment, the removed base material can be reusable, which can significantly reduce the manufacturing cost.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1A to FIG. 1D are schematic cross-sectional views of a manufacturing method of a package carrier according to an embodiment of the disclosure.

FIG. 2 is a schematic cross-sectional view of a chip package structure according to an embodiment of the disclosure.

FIG. 3A is a schematic cross-sectional view showing some steps of a manufacturing method of a package carrier according to another embodiment of the disclosure.

FIG. 3B is a schematic cross-sectional view of a chip package structure according to another embodiment of the disclosure.

FIG. 4A to FIG. 4B are schematic cross-sectional views showing some steps of a manufacturing method of a package carrier according to another embodiment of the disclosure.

### DESCRIPTION OF THE EMBODIMENTS

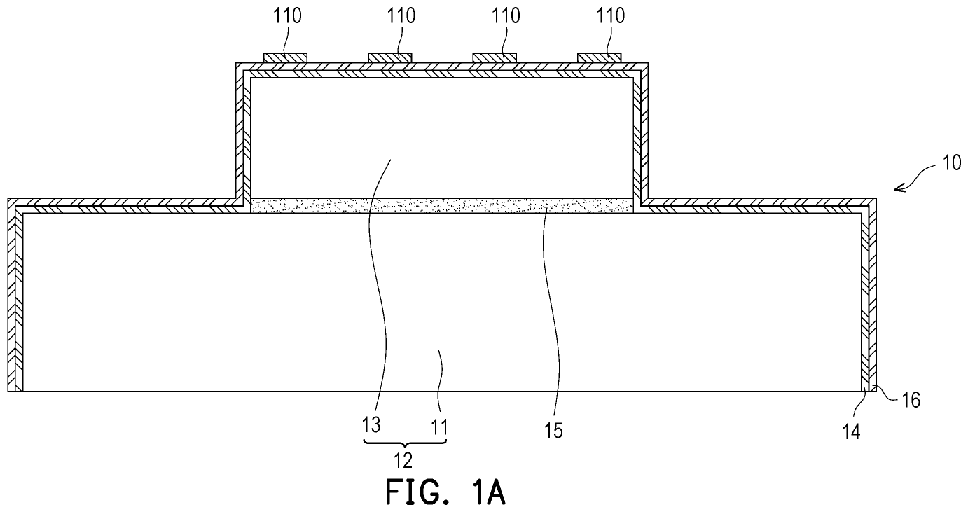

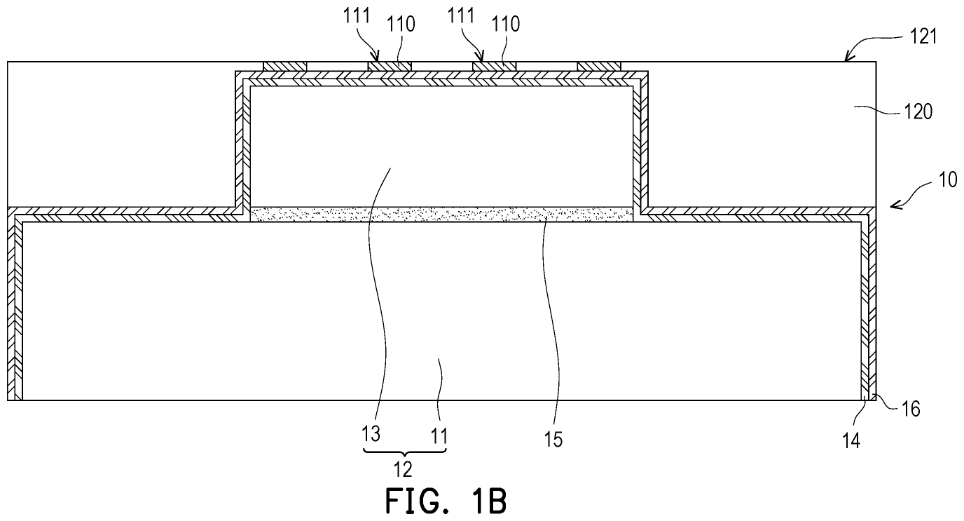

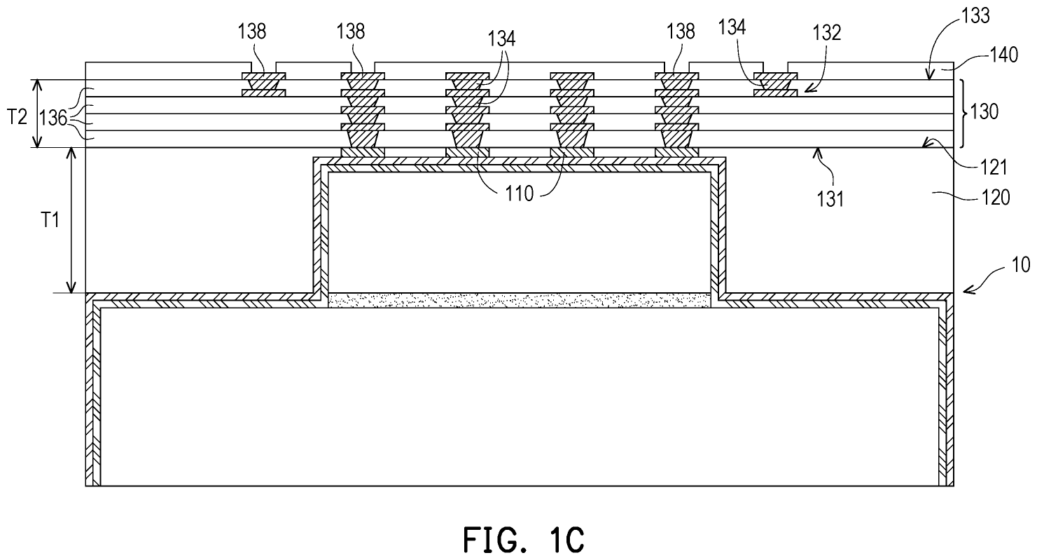

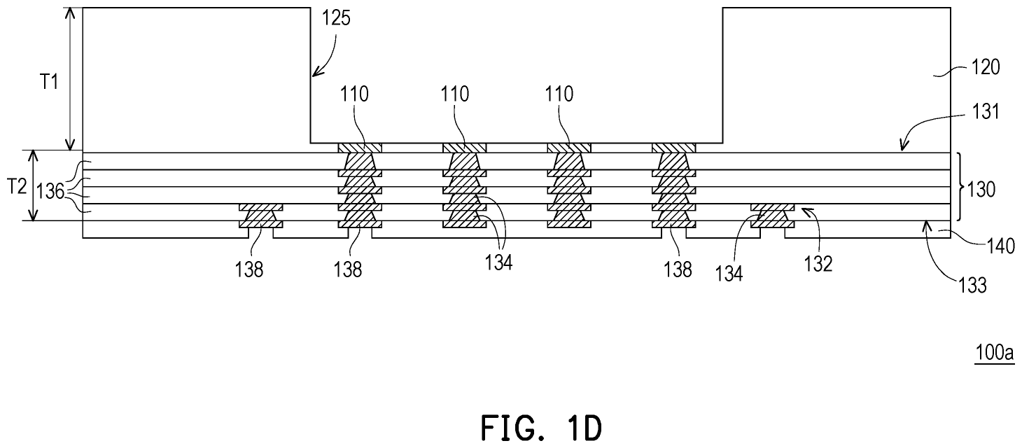

FIG. 1A to FIG. 1D are schematic cross-sectional views of a manufacturing method of a package carrier according to an embodiment of the disclosure. Regarding the manufacturing method of the package carrier of the embodiment, first, referring to FIG. 1A, a substrate 10 is provided. The substrate 10 includes a base material 12, a stainless steel layer 14, and a metal layer 16. The base material 12 includes a first part 11 and a second part 13 disposed on the first part 11 and exposing part of the first part 11. Here, the base material 12 is, for example, a glass substrate, and the first part 11 and the second part 13 of the base material 12 are fixed together through an adhesive 15 to form a convex shape. In another embodiment, the first part 11 and the second part 13 may be fixed together by plasma surface modification without using the adhesive 15. The stainless steel layer 14 is located on the base material 12 and conformally covers the base material 12. The stainless steel layer 14 directly contacts and covers the surrounding surface of the base material 12. The material of the stainless steel layer 14 is, for example, SUS 304 or other suitable models, and the thickness of the stainless steel layer 14 is, for example, between 0.05 microns and 1.5 microns. In other words, the stainless steel layer 14 can be regarded as a stainless steel film. The metal layer 16 is formed on the stainless steel layer 14 and conformally covers stainless steel layer 14. The metal layer 16 directly contacts and covers all surfaces of stainless steel layer 14. Here, the metal layer 16 is formed on the stainless steel layer 14 by, for example, electroplating, and the material of the metal layer 16 is, for example, copper, but is not limited thereto.

Next, referring to FIG. 1A again, a plurality of first conductive pillars 110 are formed on the substrate 10. The first conductive pillars 110 correspond to the second part 13 of the base material 12. That is to say, the orthographic projections of the first conductive pillars 110 and the first part 11 will overlap with the orthographic projection of the second part 13 on the first part 11. Here, the first conductive pillars 110 are formed on the metal layer 16 by, for example, electroplating. The materials of the first conductive pillars 110 are, for example, copper, but are not limited thereto.

Next, referring to FIG. 1B again, a package mold plate 120 is formed on the substrate 10. The package mold plate 120 covers the metal layer 16 and exposes an upper surface 111 of each of the first conductive pillars 110. Here, the package mold plate 120 is formed, for example, by compression molding, and the material of the package mold plate 120 is, for example, epoxy molding compound (EMC). The upper surfaces 111 of the first conductive pillars 110 can be flush with a surface 121 of the package mold plate 120 through polishing or laser perforation. In an embodiment, the periphery of the package mold plate 120 may be aligned with the periphery of the substrate 10, but is not limited thereto.

Next, referring to FIG. 1C again, a redistribution circuit layer 130 is provided on the substrate 10. The redistribution circuit layer 130 has a first surface 131 and a second surface 133 opposite to each other, and includes a plurality of redistribution circuits 132, a plurality of conductive vias 134, a plurality of dielectric layers 136, and a plurality of output pads 138. The redistribution circuits 132 and the dielectric layers 136 are alternately stacked, and the conductive vias 134 are electrically connected to two adjacent redistribution circuits 132. The conductive vias 134 are flush with the first surface 131, and part of the conductive vias 134 are electrically connected to each of the first conductive pillars 110 respectively. The output pads 138 protrude from the second surface 133. Here, the line width of each of the redistribution circuits 132 is, for example, greater than or equal to 0.5 microns and less than or equal to 30 microns. A thickness T2 of the redistribution circuit layer 130 is less than a thickness T1 of the package mold plate 120. In particular, the thickness of the edge region of the package mold plate 120 can provide mechanical stability, so that the redistribution circuit layer 130 attached to it on all four sides will not be deformed, thereby effectively supporting the redistribution circuit layer 130. In an embodiment, the thickness T1 of the package mold plate 120 is, for example, greater than or equal to 100 microns and less than or equal to 600 microns.

Next, referring to FIG. 1C again, a solder mask 140 is formed on the second surface 133 of the redistribution circuit layer 130. The solder mask 140 exposes part of the output pads 138.

Next, referring to FIG. 1C and FIG. 1D at the same time, the substrate 10 is removed by separating the board and etching off the copper, so that the middle region of the package mold plate 120 has a recess 125. The recess 125 exposes the first conductive pillars 110. Here, the first conductive pillars 110 pass through part of the package mold plate 120 located in the middle region, and the depth of the recess 125 is approximately equal to the thickness of the second part 13 of the base material 12. At this point, the production of a package carrier 100a has been completed.

Structurally, referring to FIG. 1D again, the package carrier 100a of the embodiment includes the redistribution circuit layer 130, the first conductive pillars 110, and the package mold plate 120. The redistribution circuit layer 130 has the first surface 131 and the second surface 133 opposite to each other and includes the redistribution circuits 132, the conductive vias 134, the dielectric layers 136, and the output pads 138. The redistribution circuits 132 and the dielectric layers 136 are alternately stacked, and the conductive vias 134 are electrically connected to two adjacent redistribution circuits 132. The line width of each of the redistribution circuits 132 is, for example, greater than or equal to 0.5 microns and less than or equal to 30 microns. The conductive vias 134 are flush with the first surface 131, and the output pads 138 protrude from the second surface 133. The first conductive pillars 110 are flush with the first surface 131 of the redistribution circuit layer 130 and electrically connected to part of the conductive vias 134. The package mold plate 120 is disposed on the first surface 131 of the redistribution circuit layer 130 and has the recess 125 in the middle region of the package mold plate 120. The recess 125 exposes the first conductive pillars 110. The first conductive pillars 110 pass through part of the package mold plate 120 located in the middle region, and the thickness T1 of the edge region of the package mold plate 120 can provide mechanical stability, so that the redistribution circuit layer 130 attached to it on all four sides will not be deformed. The thickness T1 of the package mold plate 120 is, for example, greater than or equal to 100 microns and less than or equal to 600 microns. In addition, the package carrier 100a further includes the solder mask 140, which is disposed on the second surface 133 of the redistribution circuit layer 130 and exposes part of the output pads 138.

In short, the thickness T1 of the edge region of the package mold plate 120 can provide mechanical stability, so that the redistribution circuit layer 130 attached to it on all four sides will not be deformed, and the recess 125 in the middle region of the package mold plate 120 can expose the first conductive pillars 110 that are electrically connected to the redistribution circuit layer 130. In this way, by disposing the package mold plate 120, not only the structural strength of the overall package carrier 100a can be increased, but also the first conductive pillars 110 exposed by the recess 125 and the output pads 138 can be electrically tested at the same time, thus improving the electrical defects detections of the package carrier 100a and reducing the logistics and inventory costs of electrical test yield losses after chip placement production. In addition, in the manufacturing method of the package carrier 100a of the embodiment, the removed base material 12 can be reusable, which can significantly reduce the manufacturing cost.

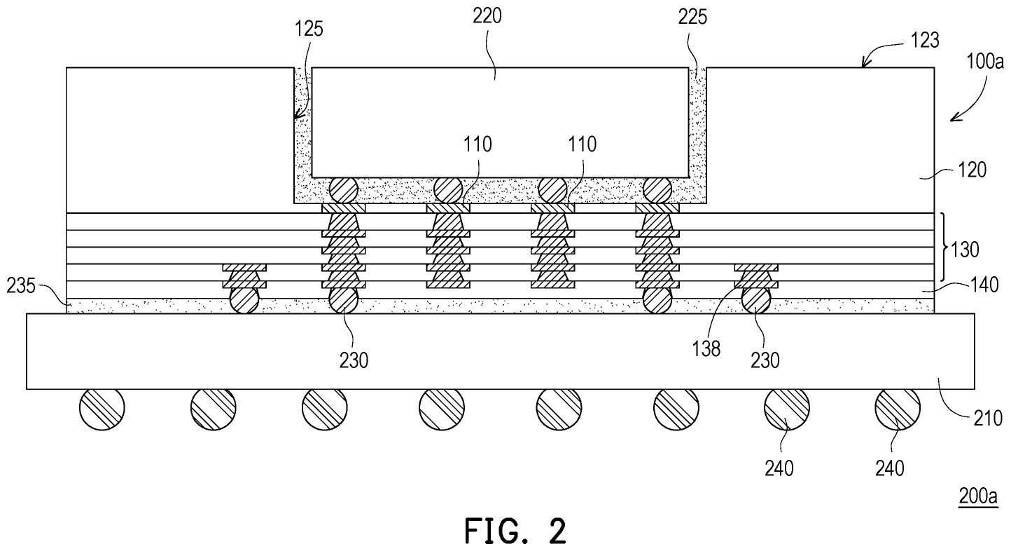

FIG. 2 is a schematic cross-sectional view of a chip package structure according to an embodiment of the disclosure. Referring to FIG. 2, a chip package structure 200a of the embodiment includes a circuit board 210, the package carrier 100a of FIG. 1D, and a chip 220. The package carrier 100a is disposed on the circuit board 210 and electrically connected to the circuit board 210. The chip 220 is disposed in the recess 125 of the package mold plate 120 and electrically connected to the first conductive pillars 110.

Specifically, in the embodiment, the chip package structure 200a also includes a plurality of solder balls 230 and an underfill 235. The solder balls 230 are disposed between the circuit board 210 and the package carrier 100a. The output pads 138 of the redistribution circuit layer 130 are electrically connected to the circuit board 210 through the solder balls 230. The underfill 235 is filled between the circuit board 210 and the package carrier 100a and covers the solder balls 230. Furthermore, the chip package structure 200a further includes an underfill 225, which is filled between the recess 125 of the package mold plate 120 and the chip 220 and covers the first conductive pillars 110. The chip 220 is fixed in the recess 125 through the underfill 225. In addition, the chip package structure 200a may further include a plurality of solder balls 240, which are disposed on a side of the circuit board 210 relatively away from the package carrier 100a for electrical connection with external circuits.

Since the chip 220 of the embodiment is disposed in the recess 125 of the package mold plate 120 and electrically connected to the first conductive pillars 110, it is not necessary to add external mold to seal the chip 220, and the package thickness of the overall chip package structure 200a can also be reduced. In addition, since the package carrier 100a can be electrically tested before packaging, the chip package structure 200a can have a better package yield after the chip 220 is packaged.

It must be noted here that the reference numerals and a part of the contents in the previous embodiment are applicable to the following embodiments, in which identical reference numerals indicate identical or similar components, and repeated descriptions of the same technical contents are omitted. For the detailed descriptions of the omitted parts, reference can be found in the previous embodiments, and no repeated description is contained in the following embodiments.

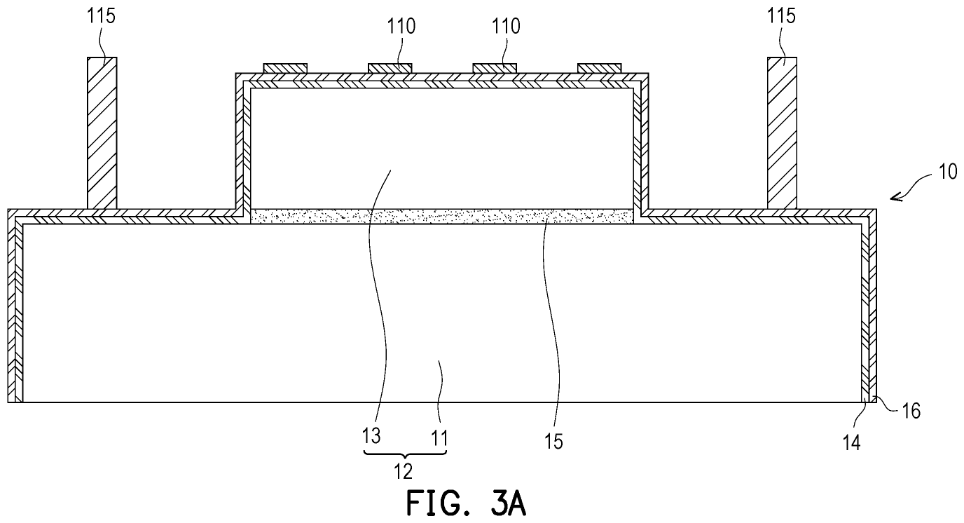

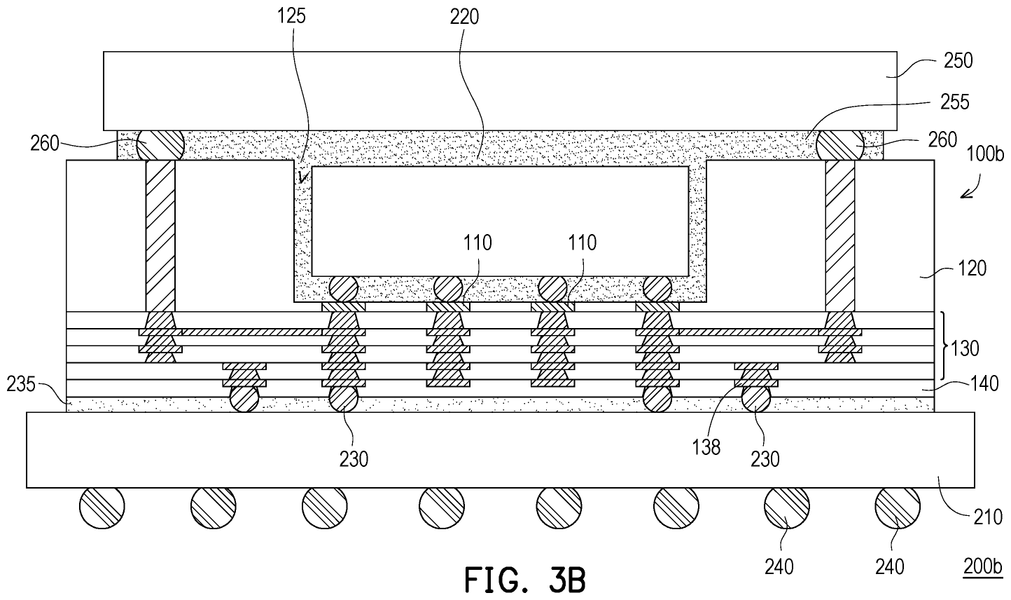

FIG. 3A is a schematic cross-sectional view showing some steps of a manufacturing method of a package carrier according to another embodiment of the disclosure. Referring to FIG. 1A and FIG. 3A at the same time, the manufacturing method of the package carrier of the embodiment is similar to the manufacturing method of the package carrier mentioned above. The difference between the two lies in that: in the embodiment, after the first conductive pillars 110 are formed in FIG. 1A and before the package mold plate 120 is formed in FIG. 1B, a plurality of second conductive pillars 115 can be formed on the substrate 10. The second conductive pillars 115 may correspond to the first part 11 exposed by the second part 13 of the base material 12. That is to say, the second conductive pillars 115 are formed on the first part 11, and the orthographic projections of the second conductive pillars 115 on the first part 11 do not overlap with the orthographic projection of the second part 13 on the first part 11. Afterwards, after continuing the manufacturing steps of FIG. 1B to FIG. 1D, a package carrier 100b in FIG. 3B can be obtained.

FIG. 3B is a schematic cross-sectional view of a chip package structure according to another embodiment of the disclosure. Referring to FIG. 2 and FIG. 3B at the same time, a chip package structure 200b of the embodiment is similar to the above-mentioned chip package structure 200a. The difference between the two lies in that: in the embodiment, the package carrier 100b further includes the plurality of second conductive pillars 115 that penetrate the package mold plate 120 and are electrically connected to the conductive vias 134 of the redistribution circuit layer 130. Furthermore, the chip package structure 200b of the embodiment also includes a POP component 250, a plurality of solder balls 260, and an underfill 255. The POP component 250 is disposed on the package carrier 100b and electrically connected to the second conductive pillars 115. The chip 220 is located between the POP component 250 and the circuit board 210. The solder balls 260 are disposed between the POP component 250 and the second conductive pillars 115, and the POP component 250 is electrically connected to the second conductive pillars 115 through the solder balls 260. The underfill 255 is filled between the POP component 250 and the package carrier 100b, between the POP component 250 and the chip 220, and between the recess 125 of the package mold plate 120 and the chip 220, and covers the first conductive pillars 110 and solder balls 260.

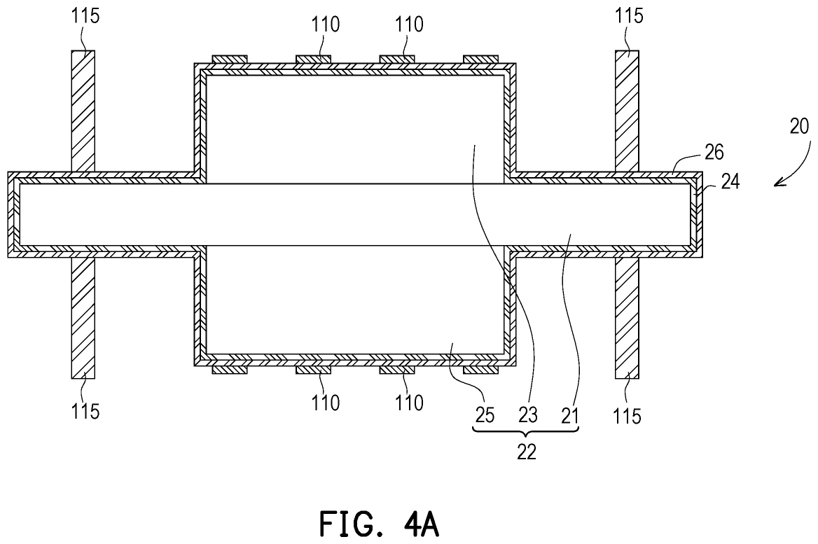

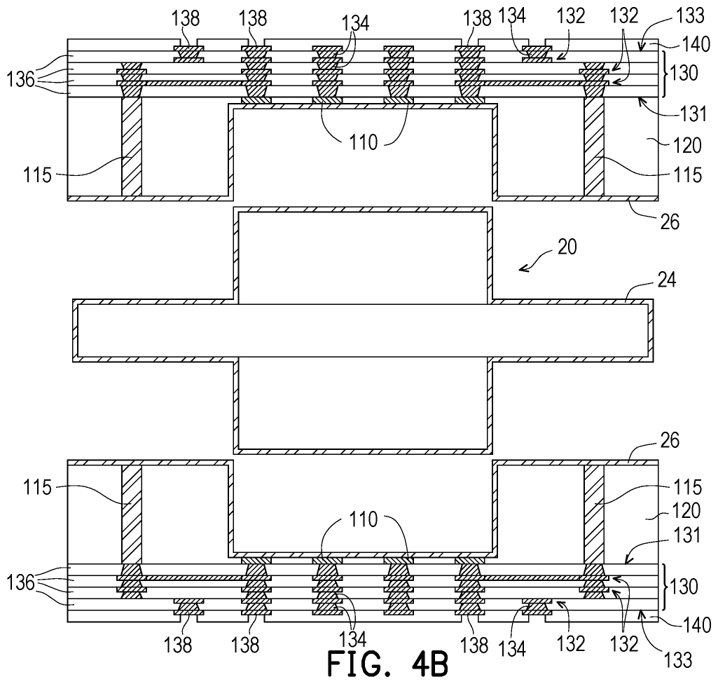

FIG. 4A to FIG. 4B are schematic cross-sectional views showing some steps of a manufacturing method of a package carrier according to another embodiment of the disclosure. Referring to FIG. 1A and FIG. 4A at the same time, the manufacturing method of the package carrier of the embodiment is similar to the manufacturing method of the package carrier mentioned above. The difference between the two lies in that: in the embodiment, a substrate 20 includes a base material 22, a stainless steel layer 24, and a metal layer 26. The base material 22 includes a first part 21 and two second parts 23 and 25 disposed on two opposite sides of the first part 21 and respectively exposing part of the first part 21. The stainless steel layer 24 is located on the base material 22 and conformally covers the base material 22. The metal layer 26 is formed on the stainless steel layer 24 and conformally covers the stainless steel layer 24. The first conductive pillars 110 are respectively formed on the second parts 23 and 25 on two opposite sides, and the second conductive pillars 115 are respectively formed on the two opposite sides of the first part 21.

Next, the steps of FIG. 1B to FIG. 1C are sequentially performed on the two opposite sides of the substrate 20. Referring to FIG. 4A and FIG. 4B at the same time, after completing the step of FIG. 1C, that is, after providing the redistribution circuit layer 130 and forming the solder mask 140, the metal layer 26 and the stainless steel layer 24 are separated by dismantling the board. Afterwards, the metal layer 26 on the package mold plate 120 can be removed by stripping copper to remove the substrate 20, thus forming two package carriers 100b shown in FIG. 3B, which can effectively increase the production capacity. In addition, the removed base material 22 can be reusable, which can effectively reduce the material cost.

To sum up, in the design of the package carrier of the disclosure, the thickness of the edge region of the package mold plate can provide mechanical stability, so that the redistribution circuit layer attached to it on all four sides will not be deformed, and the recess in the middle region of the package mold plate can expose the first conductive pillars electrically connected to the redistribution circuit layer. In this way, by disposing the package mold plate, not only the structural strength of the overall package carrier can be increased, but also the first conductive pillars exposed by the recess and the output pads can be electrically tested at the same time, thus improving the electrical reliability of the package carrier. Furthermore, when the chip is subsequently assembled on the package carrier, since the chip is located in the recess and electrically connected to the first conductive pillars, the package thickness of the overall chip package structure can be reduced and a better package yield can be achieved. In addition, in the manufacturing method of the package carrier of the embodiment, the removed base material can be reusable, which can significantly reduce the manufacturing cost.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A package carrier, comprising:
a redistribution circuit layer, having a first surface and a second surface opposite to each other, and comprising a plurality of redistribution circuits, a plurality of conductive vias, a plurality of dielectric layers, and a plurality of output pads, wherein the redistribution circuits and the dielectric layers are alternately stacked, the conductive vias are electrically connected to two adjacent redistribution circuits, the conductive vias are flush with the first surface, and the output pads protrude from the second surface;
a plurality of first conductive pillars, disposed on the first surface of the redistribution circuit layer, and electrically connected to part of the conductive vias; and
a package mold plate, disposed on the first surface of the redistribution circuit layer, wherein a middle region of the package mold plate has a recess, the recess exposes the first conductive pillars, the first conductive pillars pass through part of the package mold plate located in the middle region, and a thickness of an edge region of the package mold plate provides mechanical stability.

2. The package carrier according to claim 1, wherein the thickness of the package mold plate is greater than or equal to 100 microns and less than or equal to 600 microns.

3. The package carrier according to claim 1, wherein a line width of each of the redistribution circuits is greater than or equal to 0.5 microns and less than or equal to 30 microns.

4. The package carrier according to claim 1, further comprising:
a solder mask, disposed on the second surface of the redistribution circuit layer, and exposing part of the output pads.

5. The package carrier according to claim 1, further comprising:
a plurality of second conductive pillars, penetrating the package mold plate, and electrically connected to the conductive vias of the redistribution circuit layer.

6. A manufacturing method of a package carrier, comprising:
providing a substrate, wherein the substrate comprises a base material, a stainless steel layer, and a metal layer, the base material comprises a first part and a second part disposed on the first part and exposing part of the first part, the stainless steel layer is located on the base material and conformally covers the base material, and the metal layer is formed on the stainless steel layer and conformally covers the stainless steel layer;
forming a plurality of first conductive pillars on the substrate, wherein the first conductive pillars correspond to the second part of the base material;
forming a package mold plate on the substrate, wherein the package mold plate covers the metal layer and exposes each of the first conductive pillars;
providing a redistribution circuit layer on the substrate, wherein the redistribution circuit layer has a first surface and a second surface opposite to each other and comprises a plurality of redistribution circuits, a plurality of conductive vias, a plurality of dielectric layers, and a plurality of output pads, the redistribution circuits and the dielectric layers are alternately stacked, the conductive vias are electrically connected to two adjacent redistribution circuits, the conductive vias are flush with the first surface, part of the conductive vias are electrically connected to each of the first conductive pillars respectively, and the output pads protrude from the second surface; and
removing the substrate so that a middle region of the package mold plate has a recess, wherein the recess exposes the first conductive pillars, the first conductive pillars pass through part of the package mold plate located in the middle region, and a thickness of an edge region of the package mold plate provides mechanical stability.

7. The manufacturing method of the package carrier according to claim 6, wherein the first part and the second part of the base material are fixed together through an adhesive.

8. The manufacturing method of the package carrier according to claim 6, further comprising:
before forming the package mold plate on the substrate, forming a plurality of second conductive pillars on the substrate, wherein the second conductive pillars correspond to the first part exposed by the second part of the base material.

9. The manufacturing method of the package carrier according to claim 6, further comprising:
before removing the substrate, forming a solder mask on the second surface of the redistribution circuit layer, and exposing part of the output pads.

10. The manufacturing method of the package carrier according to claim 6, wherein the thickness of the package mold plate is greater than or equal to 100 microns and less than or equal to 600 microns.

11. The manufacturing method of the package carrier according to claim 6, wherein a line width of each of the redistribution circuits is greater than or equal to 0.5 microns and less than or equal to 30 microns.

12. The manufacturing method of the package carrier according to claim 6, wherein a material of the substrate comprises glass.

13. The manufacturing method of the package carrier according to claim 6, wherein a material of the substrate comprises fiberglass resin.

14. A chip package structure, comprising:
a circuit board;
a package carrier, disposed on the circuit board, and electrically connected to the circuit board, wherein the package carrier comprises:
a redistribution circuit layer, having a first surface and a second surface opposite to each other and comprising a plurality of redistribution circuits, a plurality of conductive vias, a plurality of dielectric layers, and a plurality of output pads, wherein the redistribution circuits and the dielectric layers are alternately stacked, the conductive vias are electrically connected to two adjacent redistribution circuits, the conductive vias are flush with the first surface, and the output pads protrude from the second surface and are electrically connected to the circuit board;
a plurality of first conductive pillars, disposed on the first surface of the redistribution circuit layer, and electrically connected to part of the conductive vias; and
a package mold plate, disposed on the first surface of the redistribution circuit layer, wherein a middle region of the package mold plate has a recess, the recess exposes the first conductive pillars, the first conductive pillars pass through part of the package mold plate located in the middle region, and a thickness of an edge region of the package mold plate provides mechanical stability; and
a chip, disposed in the recess of the package mold plate, and electrically connected to the first conductive pillars.

15. The chip package structure according to claim 14, further comprising:
a plurality of solder balls, disposed between the circuit board and the package carrier, wherein the output pads of the redistribution circuit layer are electrically connected to the circuit board through the solder balls; and
an underfill, filled between the circuit board and the package carrier, and covering the solder balls.

16. The chip package structure according to claim 14, further comprising:
an underfill, filled between the recess of the package mold plate and the chip, and covering the first conductive pillars.

17. The chip package structure according to claim 14, further comprising:
a plurality of solder balls, disposed on a side of the circuit board relatively away from the package carrier.

18. The chip package structure according to claim 14, wherein the thickness of the package mold plate is greater than or equal to 100 microns and less than or equal to 600 microns.

19. The chip package structure according to claim 14, wherein a line width of each of the redistribution circuits is greater than or equal to 0.5 microns and less than or equal to 30 microns.

20. The chip package structure according to claim 14, wherein the package carrier further comprises:
a solder mask, disposed on the second surface of the redistribution circuit layer, and exposing part of the output pads.

21. The chip package structure according to claim 14, wherein the package carrier further comprises:
a plurality of second conductive pillars, penetrating the package mold plate, and electrically connected to the conductive vias of the redistribution circuit layer.

22. The chip package structure according to claim 21, further comprising:
a POP component, disposed on the package carrier, and electrically connected to the second conductive pillars, wherein the chip is located between the POP component and the circuit board;
a plurality of solder balls, disposed between the POP component and the second conductive pillars, wherein the POP component is electrically connected to the second conductive pillars through the solder balls; and
an underfill, filled between the POP component and the package carrier, between the POP component and the chip, and between the recess of the package mold plate and the chip, and covering the first conductive pillars and the solder balls.
